(19) United States
(12) Patent Application Publication
(10) Pub. No.: US 2016/0109516 A1
(43) Pub. Date: Apr. 21, 2016

(54) Portable and Modular Logic Design Testing Module

(71) Applicant: Bassem Alhalabi, Boca Raton, FL (US)

(72) Inventor: Bassem Alhalabi, Boca Raton, FL (US)

(21) Appl. No.: 14/517,362

(22) Filed: Oct. 17, 2014

(51) Int. Cl. G01R 31/3177

(52) U.S. Cl. CPC G01R 31/3177

(57) ABSTRACT

A portable logic design testing module detachably integrates with a breadboard, and connects with other logic design modules on the breadboard to form larger testing systems. The logic design module provides input signals through at least one input module, and displays output signals through at least one output module. The module utilizes interconnecting circuits for modularizing adjacent modules, logic switches for controlling logic binary numbers, counters for incrementally manipulating the binary numbers, LEDs for displaying the binary numbers, and a display for displaying the binary numbers. The module detachably connects to the breadboard through a six-pin header to enable facilitated displacement between different regions of the breadboard. Additionally, the logic design module possesses modular characteristics, operatively connecting with adjacent logic design modules to increase bit size and testing capacity. The relatively small size, modular configuration, and cascadable capacity of the module enables replacement of logic design training kits.

### FIELD OF THE INVENTION

The present invention relates generally to a portable and modular logic design testing module. More so, a portable and modular logic design testing module detachably integrates with a circuit board, and operatively connects with additional modules for testing logical operations on the circuit board.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon.

By way of educational background, another aspect of the prior art generally useful to be aware of is that electrical circuits are typically prototyped using a printed circuit board, commonly referred to as a breadboard. A typical breadboard contains a plurality of plated through holes that are coupled to conductive pins. Discrete electrical components are soldered or simply inserted into the plated holes and coupled together by wires which are wrapped around corresponding pins. The discrete components may include integrated circuits, individual transistors, resistors, capacitors, diodes that are all connected to create an electrical circuit.

Typically, the circuitry on the breadboard must be tested so that students can learn the proper techniques and logic design for designing the circuitry. Students normally build their logic design lab exercise on the bread board using discreet logic components and hookup wires. Students will then place the breadboard on the training kit and connect the inputs and output signals to the training kit for testing. In practice, an electrical current is passed through an input and output region of the logic design training kit, from which the circuit board is attached. The logic design training kit can then indicate the status of the circuitry on the breadboard, often in the form of binary numbers combinations.

It is known that logic design laboratory experimentation is very fundamental and must accompany the class instruction hand-in-hand to complete the full experience of logic design and digital systems. Without this testing and experimentation, hands-on practical experience would not be possible. Universities typically use logic design training kits in their labs where students store and work on their breadboards. The breadboards are connected to the inputs and output regions of the training kits for testing. While this is the best known hands-on approach, the maintenance cost of those training kits is restrictive.

Many universities have tried switching to logic design breadboard simulation software, which is very cheap and convenient. But this software lacks the very much needed hands-on experience. There are technologies which are middle ground between real labs, pure software simulation, and remote labs. With remote labs students can run real experiments via an on-line interface, which means you have the convenience of software with actual electronics in action. But even this is not a satisfactory solution. Students normally buy the breadboards and get the chips from the university as a part of the lab fees. Furthermore, the training kits are a heavy expense to the university. These expenses are a burden that often prevent the university from buying new training kits when they break down.

Even though the above cited systems and methods for testing circuitry on breadboards address some of the needs of the market, a portable logic design testing module that detachably integrates with a circuit board to replace training kits is still desired. Modules have been used for analyzing and testing prototype circuits in the past, yet none with the present characteristics of the present invention. See Patent numbers: U.S. Pat. No. 3,867,672; U.S. Pat. No. 7,292,046; U.S. Pat. No. 6,459,587; and CA2322235.

### SUMMARY OF THE INVENTION

The present invention is directed to a portable logic design testing module that detachably integrates with a circuit board, such as a breadboard. The module detachably connects to the circuit board through a six-pin header, movable between different regions of the circuit board for satisfying different logical testing requirements. Additionally, the logic design module possesses modular characteristics in that it operatively connects with adjacent logic design modules to increase its bit size and testing capacity. The relatively small size, modular configuration, and cascadable capacity of the module provide a portable and inexpensive logical design testing solution.

The logic design module provides input signals through at least one input module, and displays output signals through at least one output module. The input and output modules work together to provide input and output signals, logic operations, and gates; thus enabling seamless integration with the circuit board. In essence, the logic design module provides substantially the same logic design testing capacity as the larger more expensive logic design training kit.

In one aspect, a portable and modular logic design module for testing logical operations comprises:
at least one input module configured to provide an input signal,
the at least one input module comprising a plurality of first logic pins and a plurality of first power pins, the plurality of first logic pins and the plurality of first power pins configured to enable detachable and operable connectivity by the at least one input module for testing logical operations,
the at least one input module further comprising a first input logic circuit and a first output logic circuit, the first input logic circuit and the first output logic circuit configured to enable detachable and operable connectivity between adjacent input modules; and
at least one output module configured to display an output signal,
the at least one output module comprising a plurality of second logic pins and a plurality of second power pins, the plurality of second logic pins and the plurality of second power pins configured to enable detachable and operable connectivity by the at least one input module for testing logical operations,
the at least one output module further comprising a second input logic circuit and a second output logic circuit, the second input logic circuit and the second output logic circuit configured to enable detachable and operable connectivity between adjacent output modules.

In another aspect, the plurality of first logic pins and the plurality of first power pins comprise a first 6-pin male header.

In another aspect, the plurality of first logic pins comprises four header pins correlating to binary weights of 8, 4, 2, and 1.

In another aspect, the plurality of first power pins comprises a first voltage pin and a first ground pin.

In another aspect, the plurality of second logic pins and the plurality of second power pins comprise a second 6-pin male header.

In another aspect, the plurality of second logic pins comprises four header pins correlating to binary weights of 8, 4, 2, and 1.

In another aspect, the plurality of second power pins comprises a second voltage pin and a second ground pin.

In another aspect, the first input logic circuit operatively connects to an adjacent output logic circuit from an adjacent input module.

In another aspect, the first input logic circuit, the first output logic circuit, the second input logic circuit, and the second output logic circuit comprise cascade pins.

In another aspect, the at least one input module comprises a plurality of logic switches, each logic switch having a binary weight, wherein the combination of binary weights are configured to form a four-bit logic binary number combination.

In another aspect, the plurality of logic switches comprises four logic switches.

In another aspect, the binary weight for the four logic switches is 8, 4, 2, and 1.

In another aspect, the at least one input module comprises a plurality of first indicators configured to indicate the four-bit logic binary number combination.

In another aspect, the plurality of first indicators comprises four light emitting diodes.

In another aspect, the at least one output module comprises a plurality of second indicators configured to indicate the four-bit logic binary number combination.

In another aspect, the plurality of second indicators comprises four light emitting diodes.

In another aspect, the at least one input module comprises a counter portion configured to incrementally increase or decrease the four-bit logic binary number combination.

In another aspect, the counter portion comprises a count-up button and a count-down button.

In another aspect, the at least one output module comprises a display configured to display the four-bit logic binary number combination.

In another aspect, the module comprises a battery for powering the components in the input and output modules.

One objective of the present invention is to provide logic design testing modules that plug onto a circuit board, such as a breadboard, and become an integral part of the breadboard.

Another objective is to replace the larger more expensive logic design training kit that performs substantially the same functions.

Another objective is to provide logic and power pins that form a 6-pin male header that easily engages and disengages from the input and output module for increasing portability.

Another objective is to enable the modules to operatively connect input logic circuits (C-IN) and output logic circuits (C-OUT) to form larger input and output systems in multiples that are four-bits, eight-bits, and twelve bits wide.

Yet another objective is to produce a small, portable, modular, and affordable logic design testing component.

Yet another objective is to eliminate the need for students and colleges to purchase and carry the heavier, more expensive logic design training kit with the logic design testing module.

These and other advantages of the invention will be further understood and appreciated by those skilled in the art by reference to the following written specification, claims and appended drawings.

### BRIEF DESCRIPTION OF THE DRAWINGS

The invention will now be described, by way of example, with reference to the accompanying drawings, in which:

FIG. 1 illustrates a diagram of an exemplary input module having logic pins, voltage pins, ground pins, logic switches, LEDs, counters, and input/output logic circuits, in accordance with an embodiment of the present invention; and

FIG. 2 illustrates a diagram of an exemplary output module having logic pins, voltage pins, ground pins, a display, LEDs, and input/output logic circuits, in accordance with an embodiment of the present invention.

Like reference numerals refer to like parts throughout the various views of the drawings.

### DETAILED DESCRIPTION OF THE INVENTION

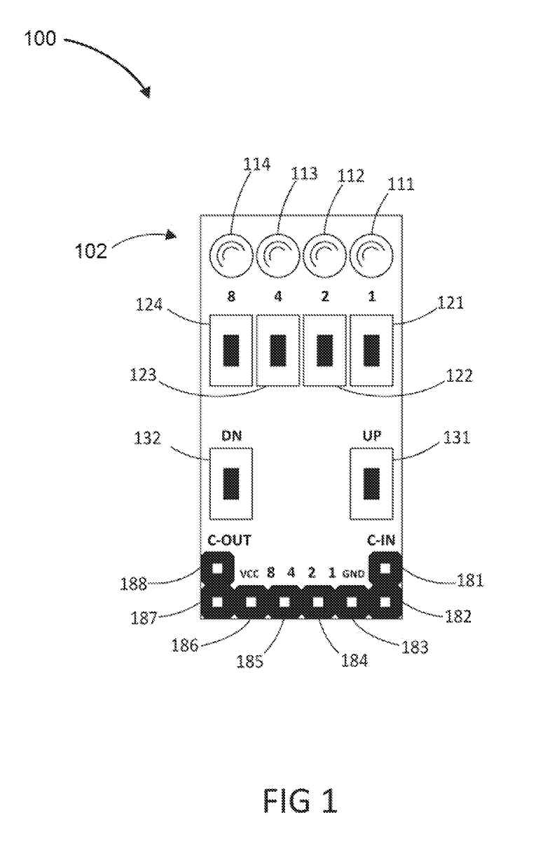

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

At the outset, it should be clearly understood that like reference numerals are intended to identify the same structural elements, portions, or surfaces consistently throughout the several drawing figures, as may be further described or explained by the entire written specification of which this detailed description is an integral part. The drawings are intended to be read together with the specification and are to be construed as a portion of the entire “written description” of this invention as required by 35 U.S.C. §112.

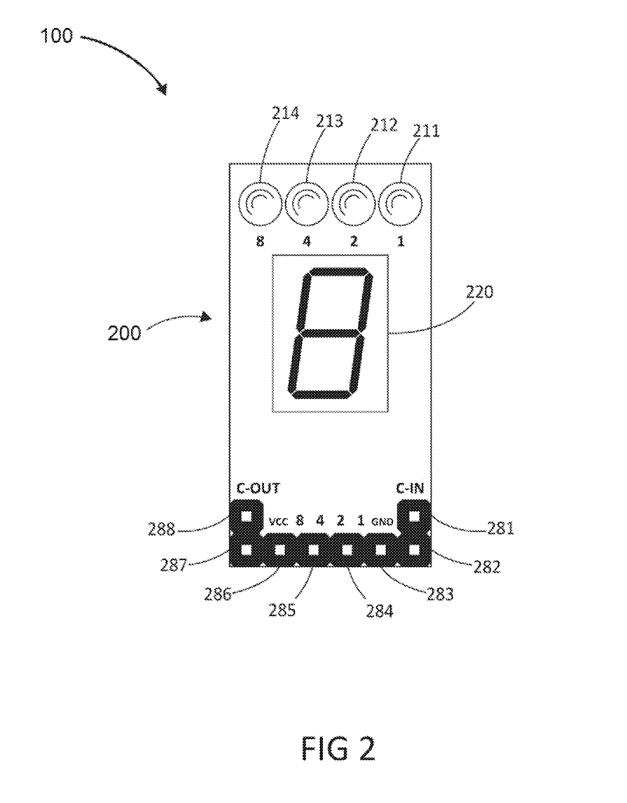

In one embodiment of the present invention, presented in FIGS. 1 and 2, a portable logic design module 100 comprises at least one input module 102 and at least one output module 200 configured to work together for testing logic design circuitry on a circuit board (not shown).

In one embodiment, the logic design module 100 is approximately 0.6″ by 1.2″, and disposed to mount on the periphery of the circuit board. This relatively small size and peripheral positioning allows for more space to build the circuitry on the circuit board. However, in other embodiments, smaller or larger modules may be used anywhere on the circuit board. The circuit board may include, without limitation, a breadboard.

The logic design module 100 detachably connects to the circuit board through a six-pin header to enable facilitated removal from the circuit board, and strategic displacement between different regions of the circuit board. Additionally, the logic design module 100 possesses modular characteristics in that it operatively connects with adjacent logic design modules 100 to increase its total bit size and testing capacity. The relatively small size, modular configuration, and cascadable capacity of the logic design module 100 provides a portable and inexpensive testing solution that can replace the larger, more expensive logic design training kits.

As referenced in FIG. 1, the logic design module 100 provides input signals through at least one input module 102. A battery (not shown) provides power to the input module 102 for generating the input signal. It is significant to note that the logic design module 100, as configured here, consumes minimal power, and thus, operates on the battery for many hours. The input module 102 comprises a plurality of first logic pins 183, 184, 185, 186 and a plurality of first power pins 182, 187 that form a first 6-pin male header. The first logic pins 183, 184, 185, 186 and the first power pins 182, 187 may easily detach and reattach with the circuit board to move the input module 102 between different regions of the circuit board. In one embodiment, the first logic pins 183, 184, 185, 186 include four header pins correlating to binary weights of 8, 4, 2, and 1 (inputs 8.4.2.1). The first power pins 182, 187 may include a first voltage pin 187 that serves as a conduit for carrying electricity through the input module 102, and a first ground pin 182 for grounding the electrical circuit from the input module 102.

The at least one input module 102 further comprises a first input logic circuit 181 and a first output logic circuit 188. In one embodiment, the first input logic circuit 181 is a C-IN cascade pin and the first output logic circuit 188 is a C-OUT cascade pin. The first input logic circuit 181 and the first output logic circuit 188 operatively connect adjacent input modules 102 to form larger input systems in multiples that are four-bits, eight-bits, and twelve bits wide. In one embodiment, the first input logic circuit 181 and the first output logic circuit 188 connect through a 2-pin male header. For two input modules 102 to work together in the circuit board, the first output logic circuit 188 of a right input module must be connected to the first input logic circuit 181 of an adjacently positioned left input module.

In some embodiments, the at least one input module 102 comprises a plurality of logic switches 121, 122, 123, 124. The logic switches 121, 122, 123, 124 may include, without limitation, buttons, toggles, and knobs that are easily displaced between two distinct positions. Each logic switch 121, 122, 123, 124 has a correlating binary weight. In one embodiment, the binary weights are 8, 4, 2, and 1, with each binary weight correlating to one of the four logic switches 121, 122, 123, 124. The combination of binary weights are manipulated by the logic switches 121, 122, 123, 124 to form a four-bit logic binary number combination ranging from 0000-1111 in binary or from $0-F in hexadecimal. The logic switches 121, 122, 123, 124 may be manipulated to move between high voltage (1) and low voltage (0). For example, toggling all the logic switches 121, 122, 123, 124 resets the four-bit logic binary number combination to zero.

In some embodiments, a counter portion 131, 132 incrementally increases or decreases the four-bit logic binary number combination. The counter portion 131, 132 may include a count-up button 131 and count-down button 132. The count-up button 131 and the count-down button 132 are manipulated to cause the four-bit logic binary number to incrementally increase or decrease by 1. In one embodiment, when the first input logic circuit 181 and the first output logic circuit 188 connection is made across adjacent input modules 102, the count-up button 131 and the count-down button 132 on the most-right input module 102 automatically affects both connected modules 102.

In some embodiments, a plurality of first indicators 111, 112, 113, 114 indicate the four-bit logic binary number combination that is created through manipulation of the logic switches 121, 122, 123, 124. The first indicators 111, 112, 113, 114 may include four light emitting diodes (LEDs). In one example, an illuminating LED indicates a high logic (1), while a light emitting diode that does not illuminate indicates a low logic (0). In this manner, the logic binary number combination can be determined quickly.

As referenced in FIG. 2, the module 100 also comprises at least one output module 200 that displays output signals received from the input module 102 and/or the circuit board. The at least one output module 200 comprises a plurality of second logic pins 283, 284, 285, 286 and a plurality of second power pins 282, 287 that form a second 6-pin male header. The second logic pins 283, 284, 285, 286 and the second power pins 282, 287 may easily detach and reattach with the circuit board to move the output module 200 between different regions of the circuit board. In one embodiment, the second logic pins 283, 284, 285, 286 include four header pins correlating to binary weights of 8, 4, 2, and 1 (outputs 8.4.2.1). The second power pins 282, 287 may include a second voltage pin 287 that serves as a conduit for carrying electricity received from the input module 102 and the circuit board. A second ground pin 282 is configured for grounding the electrical circuit.

The at least one output module 200 further comprises a second input logic circuit 281 and a second output logic circuit 288. In one embodiment, the second input logic circuit 281 is a C-IN cascade pin and the second output logic circuit 288 is a C-OUT cascade pin. The second input logic circuit 281 and the second output logic circuit 288 operatively connect adjacent output modules 200 to form larger output systems in multiples that are four-bits, eight-bits, and twelve bits wide. The second input and output logic circuits 281, 288 operatively connect through a 2-pin male header. For two output modules 200 to work together in the circuit board, the second output logic circuit 288 of a right output module must be connected to the second input logic circuit 281 of a left output module.

In some embodiments, the at least one output module 200 comprises a display 220 configured to convert, and then exhibit the four-bit logic binary number combination. The display 220 may include a 7-segment display which presents a four-bit logic binary number combination ranging from 0000-1111 in binary, or from $0-F in hexadecimal. Additionally, a plurality of second indicators 211, 212, 213, 214 indicate the four-bit logic binary number combination that is created through manipulation of the logic switches 121, 122, 123, 124, and then subsequently displayed in the display 220. The second indicators 211, 212, 213, 214 may include four light emitting diodes (LEDs). An illuminating LED indicates a high logic (1), while a light emitting diode that does not illuminate indicates a low logic (0).

Since many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What I claim is:

1. A portable and modular logic design module for testing logical operations, the module comprising:
at least one input module configured to provide an input signal,
the at least one input module comprising a plurality of first logic pins and a plurality of first power pins, the plurality of first logic pins and the plurality of first power pins configured to enable detachable and operable connectivity by the at least one input module for testing logical operations,
the at least one input module further comprising a first input logic circuit and a first output logic circuit, the first input logic circuit and the first output logic circuit configured to enable detachable and operable connectivity between adjacent input modules; and
at least one output module configured to display an output signal,
the at least one output module comprising a plurality of second logic pins and a plurality of second power pins, the plurality of second logic pins and the plurality of second power pins configured to enable detachable and operable connectivity by the at least one input module for testing logical operations,
the at least one output module further comprising a second input logic circuit and a second output logic circuit, the second input logic circuit and the second output logic circuit configured to enable detachable and operable connectivity between adjacent output modules.

2. The module of claim 1, wherein the plurality of first logic pins and the plurality of first power pins comprise a first 6-pin male header.

3. The module of claim 2, wherein the plurality of first logic pins comprises four header pins correlating to binary weights of 8, 4, 2, and 1.

4. The module of claim 3, wherein the plurality of first power pins comprises a first voltage pin and a first ground pin.

5. The module of claim 1, wherein the plurality of second logic pins and the plurality of second power pins comprise a second 6-pin male header.

6. The module of claim 5, wherein the plurality of second logic pins comprises four header pins correlating to binary weights of 8, 4, 2, and 1.

7. The module of claim 6, wherein the plurality of second power pins comprises a second voltage pin and a second ground pin.

8. The module of claim 1, wherein the first input logic circuit operatively connects to an adjacent output logic circuit from an adjacent input module.

9. The module of claim 1, wherein the first input logic circuit, the first output logic circuit, the second input logic circuit, and the second output logic circuit comprise cascade pins.

10. The module of claim 1, wherein the at least one input module comprises a plurality of logic switches, each logic switch having a binary weight, wherein the combination of binary weights are configured to form a four-bit logic binary number combination.

11. The module of claim 10, wherein the plurality of logic switches comprises four logic switches.

12. The module of claim 11, wherein the binary weight for the four logic switches is 8, 4, 2, and 1.

13. The module of claim 12, wherein the at least one input module comprises a plurality of first indicators configured to indicate the four-bit logic binary number combination.

14. The module of claim 13, wherein the plurality of first indicators comprises four light emitting diodes.

15. The module of claim 14, wherein the at least one output module comprises a plurality of second indicators configured to indicate the four-bit logic binary number combination.

16. The module of claim 15, wherein the plurality of second indicators comprises four light emitting diodes.

17. The module of claim 16, wherein the at least one input module comprises a counter portion configured to incrementally increase or decrease the four-bit logic binary number combination.

18. The module of claim 17, wherein the counter portion comprises a count-up button and a count-down button.

19. The module of claim 18, wherein the at least one output module comprises a display configured to display the four-bit logic binary number combination.

20. A portable and modular logic design module for testing logical operations, the module comprising:
at least one input module configured to provide an input signal,
the at least one input module comprising a plurality of first logic pins and a plurality of first power pins, the plurality of first logic pins and the plurality of first power pins configured to enable detachable and operable connectivity by the at least one input module for testing logical operations,
the at least one input module further comprising a first input logic circuit and a first output logic circuit, the first input logic circuit and the first output logic circuit configured to enable detachable and operable connectivity between adjacent input modules,
the at least one input module further comprising a plurality of logic switches, each logic switch having a binary weight, wherein the combination of binary weights are configured to form a four-bit logic binary number combination,
the at least one input module further comprising a plurality of first indicators configured to indicate the four-bit logic binary number combination,
the at least one input module further comprising a counter portion configured to incrementally increase or decrease the four-bit logic binary number combination; and
at least one output module configured to display an output signal,
the at least one output module comprising a plurality of second logic pins and a plurality of second power pins, the plurality of second logic pins and the plurality of second power pins configured to enable detachable and operable connectivity by the at least one input module for testing logical operations,
the at least one output module further comprising a second input logic circuit and a second output logic circuit, the second input logic circuit and the second output logic circuit configured to enable detachable and operable connectivity between adjacent output modules,
the at least one output module further comprising a plurality of second indicators configured to indicate the four-bit logic binary number combination,
the at least one output module further comprising a display configured to display the four-bit logic binary number combination.
